(19) United States
(12) Patent Application Publication
(10) Pub. No.: US 2026/0164986 A1
(43) Pub. Date: Jun. 11, 2026

(54) DISPLAY SUBSTRATE, DISPLAY APPARATUS AND MANUFACTURING METHOD FOR DISPLAY SUBSTRATE

(71) Applicant: BOE Technology Group Co., Ltd., Beijing (CN)

(72) Inventors: Chunyang WANG, Beijing (CN); Zheng LIU, Beijing (CN); Bingwei WANG, Beijing (CN); Ran LI, Beijing (CN); Caiyu QU, Beijing (CN); Dengyun CHEN, Beijing (CN); Hejin WANG, Beijing (CN)

(21) Appl. No.: 18/706,358

(22) PCT Filed: Mar. 29, 2023
(86) PCT No.: PCT/CN2023/084776

§ 371 Date: Apr. 30, 2024

(51) Int. Cl. H10K 59/80; H10K 59/12; H10K 59/122; H10K 59/131

(52) U.S. Cl. CPC H10K 59/80516; H10K 59/1201; H10K 59/122; H10K 59/131

(57) ABSTRACT

Disclosed are a display substrate, a display apparatus, and a method for manufacturing a display substrate. The display substrate includes: a substrate; a first electrode layer at a side of the substrate and including a plurality of first electrodes, and an auxiliary electrode at a periphery of the first electrodes, where an orthographic projection of the auxiliary electrode on the substrate and an orthographic projection of the first electrodes on the substrate do not overlap with each other; a pixel-defining layer at a side of the first electrode layer facing away from the substrate and including a first opening exposing the first electrode, and a second opening exposing the auxiliary electrode; a light-emitting layer at a side of the pixel-defining layer facing away from the first electrode layer, the light-emitting layer including a light-emitting portion located within the first opening and a hollow-out portion located within the second opening; a second electrode layer at a side of the light-emitting layer facing away from the pixel-defining layer, where the second electrode layer is lapped with the auxiliary electrode at the second opening.

### CROSS REFERENCE TO RELATED APPLICATIONS

This application is a national phase entry under 35 U.S.C. § 371 of International Application No. PCT/CN2023/084776, filed on Mar. 29, 2023, the entire content of which is incorporated herein by reference.

### TECHNICAL FIELD

The disclosure relates to the field of a semiconductor technology, and in particular to a display substrate, a display apparatus and manufacturing method for display substrate.

### BACKGROUND

The current display types mainly include a liquid crystal display (LCD), an organic light-emitting diode display (OLED), a plasma display panel (PDP) and an electronic ink display. Among them, the OLED display is recognized by the industry as the third generation display technology after LCD display due to its advantages such as thinness, active light emission, fast response speed, wide viewing angle, rich color and high brightness, low power consumption, high and low temperature resistance, and it can be widely used in smart phones, tablet PCs, TVs and other terminal products.

### SUMMARY

Embodiments of the disclosure provide a display substrate, including: a substrate; a first electrode layer at a side of the substrate and including a plurality of first electrodes, and an auxiliary electrode located at a periphery of the first electrodes, where an orthographic projection of the auxiliary electrode on the substrate and an orthographic projection of the first electrode on the substrate do not overlap with each other; a pixel-defining layer at a side of the first electrode layer facing away from the substrate, and including a first opening exposing the first electrode, and a second opening exposing the auxiliary electrode; a light-emitting layer at a side of the pixel-defining layer facing away from the first electrode layer, where the light-emitting layer includes a light-emitting portion located within the first opening, and a hollow-out portion located within the second opening; and a second electrode layer at a side of the light-emitting layer facing away from the pixel-defining layer, where the second electrode layer is lapped with the auxiliary electrode at the second opening.

In some embodiments, the auxiliary electrode is in a grid pattern having a plurality of third openings, and the first electrodes are located within the third openings.

In some embodiments, there is a gap between the auxiliary electrode and the first electrode.

In some embodiments, a shape of the third opening is same as a shape of the first electrode located within the third opening.

In some embodiments, at least part of the third openings are of different sizes.

In some embodiments, the first electrode layer further includes a first connector at an end of the auxiliary electrode, and a second connector located at the other end of the auxiliary electrode. The first connector and the second connector is configured to apply a voltage to the auxiliary electrode to burn out the light-emitting layer at the second opening after forming the light-emitting layer, to form the hollow-out portion; and an outer contour of the auxiliary electrode is a rectangle, and the first connector and the second connector are located at two ends of a diagonal of the rectangle, respectively.

In some embodiments, the auxiliary electrode includes a plurality of first sub-auxiliary electrodes extending in a first direction and arranged in a second direction, and a plurality of second sub-auxiliary electrodes connecting adjacent first sub-auxiliary electrodes. The first connector is connected with a first sub-auxiliary electrode located at an outer edge of the auxiliary electrode, and the second connector is connected with a first sub-auxiliary electrode at the other outer edge of the auxiliary electrode; and part of the plurality of second sub-auxiliary electrodes are disconnected.

In some embodiments, the plurality of first sub-auxiliary electrodes includes a first sub-electrode group and a second sub-electrode group arranged alternately along the second direction; and the first sub-electrode group and the second sub-electrode group each includes at least one of the plurality of first sub-auxiliary electrodes; and the disconnected second sub-auxiliary electrodes are located only within the first sub-electrode group, and a same first sub-electrode group at least includes one second sub-auxiliary electrode for connecting adjacent first sub-auxiliary electrodes.

In some embodiments, second sub-auxiliary electrodes for connecting adjacent first sub-auxiliary electrodes within two adjacent first sub-electrode groups are located at different ends of the display substrate in the first direction.

In some embodiments, second sub-electrode electrodes within the second sub-electrode group are all connected with the adjacent first sub-auxiliary electrodes.

In some embodiments, adjacent first sub-electrode group and second sub-electrode group share one first sub-auxiliary electrode.

In some embodiments, the display substrate further includes a planarization layer between the substrate and the first electrode layer, and a heat insulating layer between the planarization layer and the first electrode layer and in contact with the auxiliary electrode. An orthographic projection of the heat insulating layer on the substrate covers the orthographic projection of the auxiliary electrodes on the substrate, and the orthographic projection of the heat insulating layer on the substrate and the orthographic projection of the first electrodes on the substrate do not overlap with each other.

In some embodiments, the heat insulating layer has a grid pattern with a plurality of fourth openings in one-to-one correspondence with the third openings, and an orthographic projection of the third opening on the substrate covers an orthographic projection of the fourth opening on the substrate.

In some embodiments, a shape of the orthographic projection of the third opening on the substrate is same as a shape of the orthographic projection of the fourth opening on the substrate.

In some embodiments, a line width of the heat insulating layer is greater than a line width of the auxiliary electrode.

In some embodiments, a material of the heat insulating layer includes: silicon dioxide or silicon nitride.

In some embodiments, the display substrate further includes an insulating layer between the substrate and the first electrode layer, and a third electrode layer between the insulating layer and the substrate. The third electrode layer includes a plurality of signal lines, and a third electrode insulated from the signal lines. The insulating layer includes a via exposing the third electrode; and the auxiliary electrode is lapped with the third electrode through the via.

In some embodiments, the third electrode layer includes a source-drain layer, a first gate layer, and/or a second gate layer.

In some embodiments, the signal lines includes: a data line, a common electrode lead, and/or a gate line.

In some embodiments, the insulating layer includes a planarization layer, an interlayer dielectric layer, a first gate insulating layer and/or a second gate insulating layer.

In some embodiments, the display substrate further includes a light-emitting functional portion at an inner wall of the second opening.

In some embodiments, the light-emitting functional portion includes: a first sub light-emitting functional portion, and a second sub light-emitting functional portion located at a side of the first sub light-emitting functional portion away from the inner wall of the second opening; the first sub-luminescent functional portion includes: a hole transport layer and/or an electron blocking layer; and the second sub-luminescent functional portion includes: an electron transport layer and/or a hole blocking layer.

Embodiments of the disclosure provide a display apparatus including the display substrate provided by the embodiments of the disclosure.

Embodiments of the disclosure provide a method for manufacturing the display substrate, including: providing the substrate; forming the first electrode layer at a side of the substrate, where the first electrode layer includes the plurality of first electrodes, and the auxiliary electrode surrounding the first electrodes, and the orthographic projection of the auxiliary electrode on the substrate and the orthographic projection of the first electrodes on the substrate does not overlap with each other; forming a pixel-defining layer at a side of the first electrode layer facing away from the substrate, where the pixel-defining layer includes the first opening exposing the first electrode, and the second opening exposing the auxiliary electrode; forming the light-emitting layer at a side of the pixel-defining layer facing away from the first electrode layer; applying a voltage to the auxiliary electrode to burn out the light-emitting layer at the position of the auxiliary electrode; and forming the second electrode layer at a side of the light-emitting layer facing away from the first electrode layer to allow the second electrode layer to be lapped with the auxiliary electrode at the second opening.

### BRIEF DESCRIPTION OF FIGURES

FIG. 1 is a first schematic diagram of a display substrate provided by an embodiment of the disclosure.

FIG. 2 is a first schematic diagram of an auxiliary electrode provided by an embodiment of the disclosure.

FIG. 3 is a second schematic diagram of an auxiliary electrode provided by an embodiment of the disclosure.

FIG. 4 is a schematic diagram of an auxiliary electrode and a first electrode provided by embodiments of the disclosure.

FIG. 5 is a third schematic diagram of an auxiliary electrode provided by an embodiment of the disclosure.

FIG. 6 is a second schematic diagram of a display substrate provided by an embodiment of the disclosure.

FIG. 7 is a schematic diagram of a heat insulating layer provided by an embodiment of the disclosure.

FIG. 8 is a third schematic diagram of a display substrate provided by an embodiment of the disclosure.

FIG. 9 is a fourth schematic diagram of a display substrate provided by an embodiment of the disclosure.

FIG. 10 is a flow chart for manufacturing the display substrate provided by embodiments of the disclosure.

### DETAILED DESCRIPTION

In order to make the objectives, technical solutions and advantages of the embodiments of the disclosure clearer, the technical solutions of the embodiments of the disclosure are described clearly and completely below with reference to the drawings of the embodiments of the disclosure. Apparently, the described embodiments are some, not all, of the embodiments of the disclosure. Based on the described embodiments of the disclosure, all other embodiments obtained by those of ordinary skill in the art without inventive efforts fall within the protection scope of the disclosure.

Unless otherwise indicated, the technical or scientific terms used in the disclosure shall have the usual meanings understood by a person of ordinary skill in the art to which the disclosure belongs. The words “first”, “second” and the like used in the disclosure do not indicate any order, quantity or importance, but are only used to distinguish different components. The word “including” or “containing” and the like, means that an element or item preceding the word covers an element or item listed after the word and the equivalent thereof, without excluding other elements or items. The word “connection” or “coupling” and the like is not restricted to physical or mechanical connection, but may include electrical connection, whether direct or indirect. The terms “inside”, “outside”, “up”, “down”, etc., are used to indicate relative positional relationships, and when the absolute position of the described object changes, the relative positional relationship may change accordingly.

The “approximately” or “substantially the same” as used herein includes the stated value and means within an acceptable range of deviation from the specific value, as determined by one of ordinary skill in the art, taking into account the measurements discussed and the errors associated with the measurement of the specific quantity (i.e., the limitations of the measurement system). For example, “substantially the same” may mean that the difference relative to the stated value is within one or more standard deviations, or within ±30%, ±20%, ±10%, ±5%.

In the drawings, to facilitate clear illustration, thickness of layers, films, panels, regions, etc., has been enlarged. Cross-sectional views based on schematic diagrams of idealized embodiments are used for illustrating exemplary embodiments. Thus, variations in shape that are anticipated as results of, for example, manufacturing technology and/or tolerances are foreseeable. Therefore, embodiments described herein should not be interpreted as limited to the specific shape of regions shown in the drawings but rather include deviations in shape resulting from, for example, manufacturing. For example, regions shown as flat may typically have rough and/or non-linear features. Additionally, sharp corners shown may be rounded. Thus, the regions shown in the drawings are illustrative in nature, and their shapes are not intended to represent the precise shape of regions, and they are not intended to limit the scope of the claims.

For clarity and conciseness of the following description of embodiments disclosed herein, detailed descriptions of known functions and known components are omitted.

Embodiments of the disclosure provide a display substrate, including:
a substrate 1;
a first electrode layer 2 at a side of the substrate 1, including a plurality of first electrodes 21, and an auxiliary electrode 22 located at a periphery of the first electrodes 21, where an orthographic projection of the auxiliary electrode 22 on the substrate 1 and an orthographic projection of the first electrodes 21 on the substrate 1 do not overlap with each other;
a pixel-defining layer 3 at a side of the first electrode layer 2 facing away from the substrate 1, including a first opening 31 exposing the first electrode 21, and a second opening 32 exposing the auxiliary electrode 22;
a light-emitting layer 4 at a side of the pixel-defining layer 3 facing away from the first electrode layer 2, where the light-emitting layer 4 includes a light-emitting portion 41 located in the first opening 31, and a hollow-out portion 42 located in the second opening 32; specifically, in the process of fabricating the display substrate, while forming the light-emitting layer 4, the light-emitting layer 4 may be formed within the second opening 32, and then in a subsequent process, the light-emitting layer 4 within the second opening 32 may be burned out by applying voltage to the auxiliary electrodes 22, and thus the final display substrate does not have the light-emitting portion 41 within the second opening 32 of the pixel-defining layer 3; and
a second electrode layer 5 at a side of the light-emitting layer 4 facing away from the pixel-defining layer 3, where the second electrode layer 5 is lapped with the auxiliary electrode 22 at the second opening 32.

In the embodiments of the disclosure, the first electrode layer 2 includes a plurality of first electrodes 21, and an auxiliary electrode 22 disposed at the periphery of the first electrodes 21, and after the preparation of the light-emitting layer 4, the process of applying voltage to the auxiliary electrode 22 surrounding the first electrodes 41 is added to cause the auxiliary electrode 22 surrounding the first electrodes 41 to be heated up, and further causes the light-emitting layer 4 directly above the auxiliary electrode to be burned out, and then the second electrode layer 5 is formed. By utilizing the conventional first electrode layer 2 as the auxiliary electrode, removing the light-emitting layer 4 above the auxiliary electrode by short-circuiting heating, the lapping connection between the auxiliary electrode and the second electrode layer 5 can be realized, to reduce the resistance of the second electrode layer 5.

In some embodiments, the first electrode layer 2 may be an anode layer, the second electrode layer 5 may be a cathode layer, and the auxiliary electrode 22 may be an auxiliary cathode.

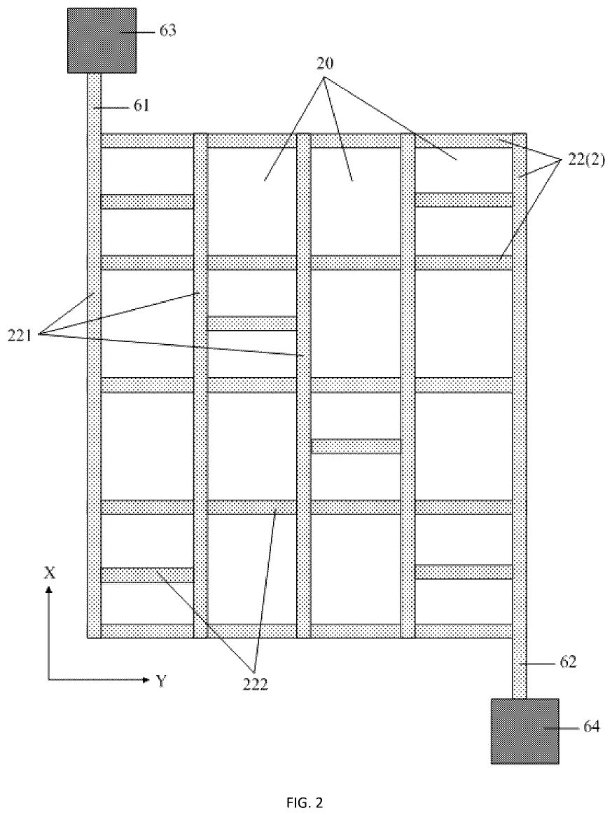

In some embodiments, as shown in FIG. 2 and FIG. 4, the auxiliary electrode 22 is in a grid pattern with a plurality of third openings 20, and the first electrode 21 is located within the third opening 20. In the embodiments of the disclosure, the auxiliary electrode 22 is in the grid shape having a plurality of third openings 20, and the first electrode 21 is disposed within the third opening 20, so as to realize that the auxiliary electrode 22 is arranged in the same layer as the first electrodes 21, and thereby simplifying the fabrication process of the display substrate.

In some embodiments, see FIG. 2 and FIG. 4, there is a gap 220 between the auxiliary electrode 22 and the first electrode 21. In the embodiments of the disclosure, the gap 220 is provided between the auxiliary electrode 22 and the first electrode 21 to avoid a case that when the auxiliary electrode 22 is connected with the first electrode 21, the auxiliary electrode 22 is applied with voltage to burn the light-emitting layer 4 directly above the auxiliary electrode 22, causing the first electrode 21 to be applied with voltage together, which may burn the light-emitting layer 4 directly above the first electrode 21 and affect the normal display of the display substrate.

In some embodiments, referring to FIG. 2 and FIG. 4, a shape of the third opening 20 is the same as the shape of the first electrode 21 located within the third opening 20. Specifically, for example, the shape of the third opening 20 and the shape of the first electrode 21 located within the third opening 20 may both be rectangular or, alternatively, may both be oval, circular, square, hexagonal, and the like. In embodiments of the disclosure, the shape of the third opening 20 is the same as the shape of the first electrode 21 located within the third opening 20, so that the first electrode 21 has a maximum pattern shape to increase the aperture ratio of the display substrate.

In some embodiments, see FIG. 2 and FIG. 4, at least part of the third openings 20 are of different sizes. In the embodiments of the disclosure, at least part of the third openings 20 have different sizes so as to accommodate the first electrodes 21 with different sizes.

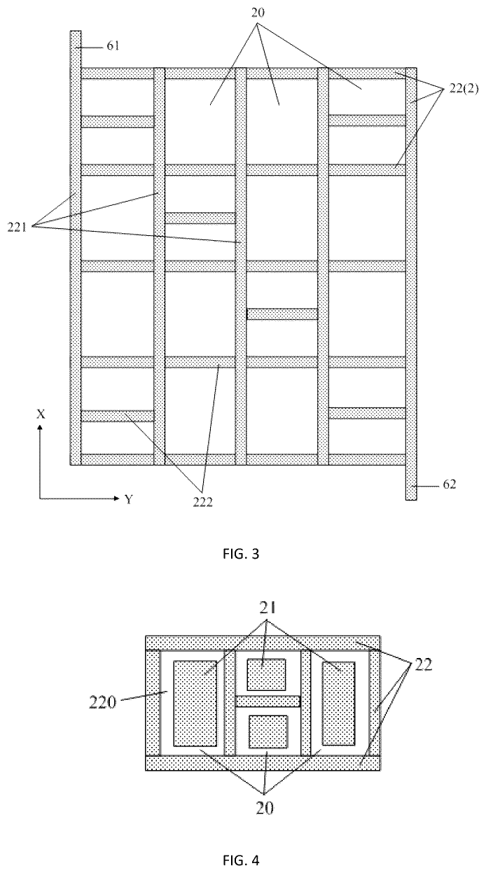

In some embodiments, see FIG. 2, FIG. 3, and FIG. 4, the first electrode layer 2 further includes a first connector 61 located at an end of the auxiliary electrode 22, and a second connector 62 located at the other end of the auxiliary electrode 22. The first connector 61 and the second connector 62 are configured to apply the voltage to the auxiliary electrode 22 after forming the light-emitting layer 4 to burn the light-emitting layer 4 at the second opening 32, thereby forming the hollow-out portion 42. The outer contour of the auxiliary electrode 22 is a rectangle, and the first connector 61 and the second connector 62 are located at two ends of the diagonal of the rectangle, respectively. In the embodiments of the disclosure, the first connector 61 and the second connector 62 are respectively located at two ends of the diagonal of the rectangle, which can make the circuit formed by the auxiliary electrode 22 as a whole longer, and the distribution of the current in the various branch circuits is roughly uniform, avoiding that when the first connector 61 and the second connector 62 are respectively located at two adjacent edges of the rectangle, it may cause some branch circuits have a larger current, and other branch circuits have a smaller current, which may lead to an uneven distribution of the current, and which in turn may lead to a situation that some of the light-emitting layer directly above the auxiliary electrode 22 is burned and the other is not burned.

In some embodiments, as shown in FIG. 2 and FIG. 3, the first connector 61 may be connected with a first power pad 63, and the second connector 62 may be connected with a second power pad 64, so that when the light-emitting layer 4 at the auxiliary electrode 22 is burned, the first power pad 63 and the second power pad 64 may be used to apply voltage to the first connector 61 and the second connecting pad 62 correspondingly; and after burning the light-emitting layer 4 at the auxiliary electrode 22, the first power pad 63 and the second power pad 64 may be removed.

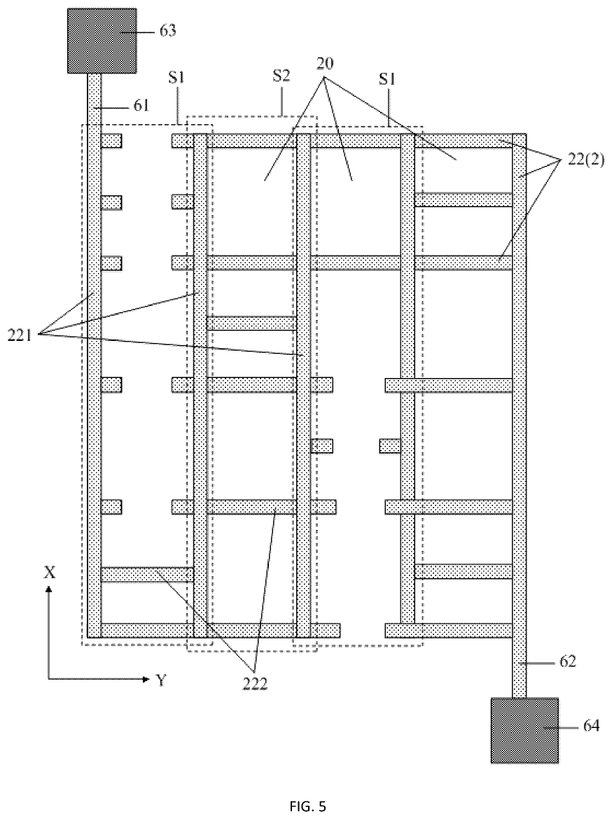

In some embodiments, as shown in FIG. 5, the auxiliary electrode 22 includes a plurality of first sub-auxiliary electrodes 221 extending along a first direction X and arranged along a second direction Y, and a plurality of second sub-auxiliary electrodes 222 connecting adjacent first sub-auxiliary electrodes 221; the first connector 61 is connected with a first sub-auxiliary electrode 221 located at an outer edge of the auxiliary electrode 22, the second connector 62 is connected with a first sub-auxiliary electrode 221 located at the other outer edge of the auxiliary electrode 22; and some of the plurality of second sub-auxiliary electrodes 222 are disconnected. In the embodiments of present disclosure, some of the second sub auxiliary electrode 222 is disconnected, i.e., the ring-shaped auxiliary electrode 22 is partially open-circuited, so that the ring-shaped metal wire forms a series wire, which can improve the situation of uneven heating caused by short-circuiting, and realize that the auxiliary electrode 22 is uniformly heated, thereby avoiding the problem that the light-emitting layer which is locally overheated 4 is removed, while the light-emitting layer 4 is not removed in some places.

In some embodiments, as shown in FIG. 5, the plurality of first sub-auxiliary electrodes 221 includes first sub-electrode groups S1 and second sub-electrode groups S2 arranged alternately along the second direction Y; the first sub-electrode group S1 and the second sub-electrode group S2 each includes at least one first sub-auxiliary electrode 221. Specifically, adjacent first sub-electrode group S1 and second sub-electrode group S2 may share one first sub-auxiliary electrode 221; the disconnected second sub-auxiliary electrodes 222 are located only in the first sub-electrode group S1, and the same one first sub-electrode group S1 includes at least one second sub-auxiliary electrode 222 for connecting adjacent first sub-auxiliary electrodes 221. In this way, the auxiliary electrodes 22 can be made to form a series wire to a large extent, to get a better improvement on the short-circuiting heating unevenness situation. The auxiliary electrodes 22 can be heated uniformly to a large extent, thereby avoiding the problem that the light-emitting layer 4 which is locally overheated is removed while the light-emitting layer 4 is not removed in some places.

In some embodiments, as shown in FIG. 5, second sub-auxiliary electrodes 222 for connecting adjacent first sub-auxiliary electrodes 221 in two adjacent first sub-electrode groups S1 are located at different ends of the display substrate in the first direction. Specifically, as shown in FIG. 5, for example, the second sub-auxiliary electrode 222 for connecting the adjacent first sub-auxiliary electrodes 221 within the first one of first sub-electrode groups S1 from the left is located at a lower end of the display substrate, and the second sub-auxiliary electrode 222 for connecting the adjacent first sub-auxiliary electrodes 221 within the second one of first sub-electrode groups S1 from the left is located at an upper end of the display substrate. In this way, the auxiliary electrodes 22 can be made to form a series wire to a large extent, to get a better improvement on the short-circuiting heating unevenness situation. The auxiliary electrodes 22 can be heated uniformly to a large extent, thereby avoiding the problem that the light-emitting layer 4 which is locally overheated is removed while the light-emitting layer 4 is not removed in some places.

In a possible implementation, as shown in FIG. 5, the second sub auxiliary electrodes 222 within the second sub-electrode group S2 are all connected with the adjacent first sub auxiliary electrodes 221.

In some embodiments, as shown in FIG. 5, adjacent first sub-electrode group S1 and second sub-electrode group S2 share a first sub auxiliary electrode 221.

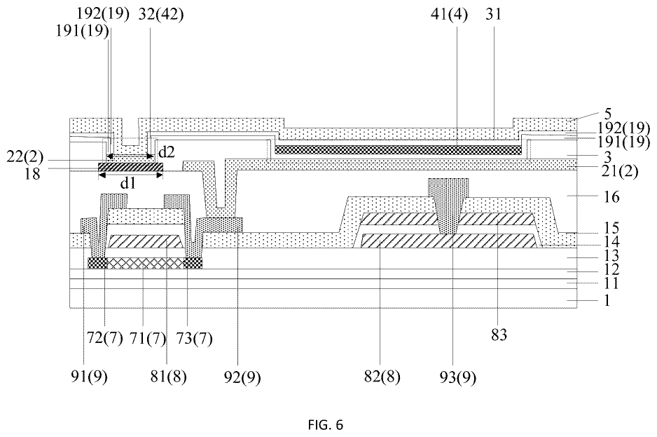

In some embodiments, as shown in FIG. 6, the display substrate further includes a planarization layer 16 between the substrate 1 and the first electrode layer 2, and a heat insulating layer 18 between the planarization layer 16 and the first electrode layer 2 and in contact with the auxiliary electrode 22, an orthographic projection of the heat insulating layer 18 on the substrate 1 covers an orthographic projection of the auxiliary electrode 22 on the substrate 1, and the orthographic projection of the heat insulating layer 18 on the substrate 1 and an orthographic projection of the first electrode 21 on the substrate 1 do not overlap with each other. In the embodiments of the disclosure, the display substrate further includes the heat-insulating layer 18, and the heat insulating layer 18 is located only at the position where the auxiliary electrode 22 is located, which can prevent a problem that the planarization layer 16 may be burned out when heating the auxiliary electrode 22, and the heat insulating layer 18 is not provided at the position where the first electrode 21 is located to avoid an influence on the brightness of light emitted from the display substrate can be avoided.

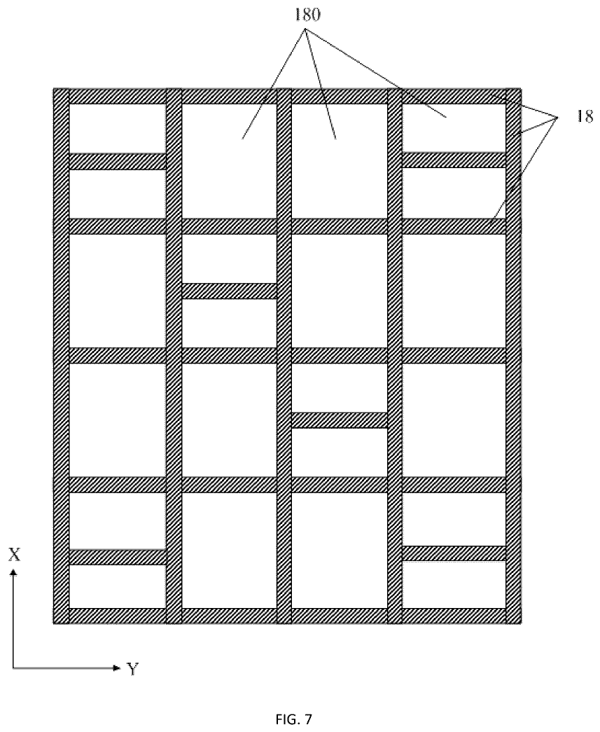

In some embodiments, as shown in FIG. 6 and FIG. 7, the heat-insulating layer 18 has a grid pattern with a plurality of fourth openings 180, the fourth openings 180 are in a one-to-one correspondence with the third openings 220, and an orthographic projection of the third openings 220 on the substrate 1 covers an orthographic projection of the fourth openings 180 on the substrate 1. That is, an area of the orthographic projection of the third opening 220 on the substrate 1 is larger than an area of the orthographic projection of the fourth opening 180 on the substrate 1, so that a line width d1 of the heat insulating 18 is larger than a line width d2 of the auxiliary electrode 22.

In some embodiments, as shown in FIGS. 2-3, and FIG. 7, a shape of the orthographic projection of the third openings 220 on the substrate 1 is the same as a shape of the orthographic projection of the fourth openings 180 on the substrate 1. Specifically, for example, the shape of the third opening 20 and the shape of the fourth opening 180 may both be rectangular or, alternatively, may both be oval, circular, square, hexagonal, etc.

In some embodiments, as shown in FIG. 6, the line width d1 of the heat insulating 18 is greater than the line width d2 of the auxiliary electrode 22, so as to completely cover the auxiliary electrode 22 and provide effective protection for the planarization layer 16.

In some embodiments, the material of the heat insulating layer 18 may include: silicon dioxide or silicon nitride. In this way, it has a better heat insulation effect.

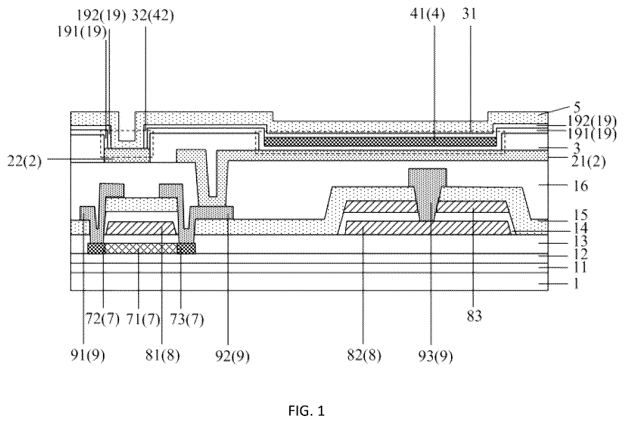

In some embodiments, as shown in FIG. 1 and FIG. 6, the display substrate further includes a light-emitting functional portion 19 at the inner wall of the second opening 32. Specifically, the light-emitting functional portion 19 may be located in the first opening 31. Specifically, the light-emitting portion 41 may include an organic light-emitting layer, or the light-emitting functional portion 19 may not include an organic light-emitting layer.

In some embodiments, as shown in FIG. 1 and FIG. 6, the light-emitting functional portion 19 includes: a first sub light-emitting functional portion 191, and a second sub light-emitting functional portion 192 located at a side of the first sub light-emitting functional portion 191 away from the inner wall of the second opening 32.

The first sub light-emitting functional portion 191 may include: a hole transport layer and/or an electron blocking layer.

The second sub light-emitting functional portion 192 may include: an electron transport layer and/or a hole blocking layer.

In some embodiments, as shown in FIG. 1 and FIG. 6, the display substrate may further include an active layer 7 between the substrate 1 and the planarization layer 16, a first gate layer 8 between the active layer 7 and the planarization layer 16, a second gate layer 83 between the first gate layer 8 and the planarization layer 16, and a source-drain layer 9 between the second gate layer 83 and the planarization layer 16. The active layer 7 may include a first active portion and a second active portion 74; the first active portion may include a channel region 71, a source region 72 located at a side of the channel region 71, and a drain region 73 located at the other side of the channel region. The first gate layer 8 may include a first gate 81, and a second gate 82. The source-drain layer 9 may include a source 91, a drain 92, and a first signal line 93, herein the source electrode 91 may be electrically connected with the source region 72, and the drain electrode 92 may be electrically connected with the drain region 73. The first electrode 21 may be electrically connected with the drain electrode 92. Specifically, the second gate 82 may serve as one end of a capacitor, the second gate layer 83 may serve as the other end of the capacitor, and the first signal line 93 may serve as a signal line connected with the capacitor.

In some embodiments, as shown in FIG. 1 and FIG. 6, the display substrate may further include a flexible substrate 11 between the substrate 1 and the active layer 7, a buffer layer 12 between the flexible substrate 11 and the active layer 7, a first gate insulating layer 13 between the active layer 7 and the first gate layer 8, a second gate insulating layer 14 between the first gate layer 8 and the second gate layer 83, and an interlayer dielectric layer 15 between the second gate insulating layer 14 and the source-drain layer 9.

In some embodiments, the display substrate further includes an insulating layer (not shown in the drawings) between the substrate 1 and the first electrode layer 2, and a third electrode layer (not shown in the drawings) between the insulating layer and the substrate 1. The third electrode layer includes a plurality of signal lines (not shown in the drawings) and a third electrode (not shown in the drawings) that is insulated from the signal lines. The insulating layer includes a via (not shown in the drawings) that exposes the third electrode. The auxiliary electrode 22 is lapped with the third electrode through the via. In embodiments of the disclosure, the lap connection of the auxiliary electrode 22 with the third electrode of the third electrode layer is added to cause the third electrode of the third electrode layer and the ring-shaped auxiliary electrode 22 to together form the auxiliary cathode, further reducing the resistance of the second electrode layer.

In some embodiments, the third electrode layer may include a source-drain layer 9, a first gate layer 8, and/or a second gate layer 83.

In some embodiments, the signal lines may include: a data line, a common electrode line, and/or a gate line.

In some embodiments, the insulating layer includes a planarization layer 16, an interlayer dielectric layer 15, a first gate insulating layer 13, and/or a second gate insulating layer 14.

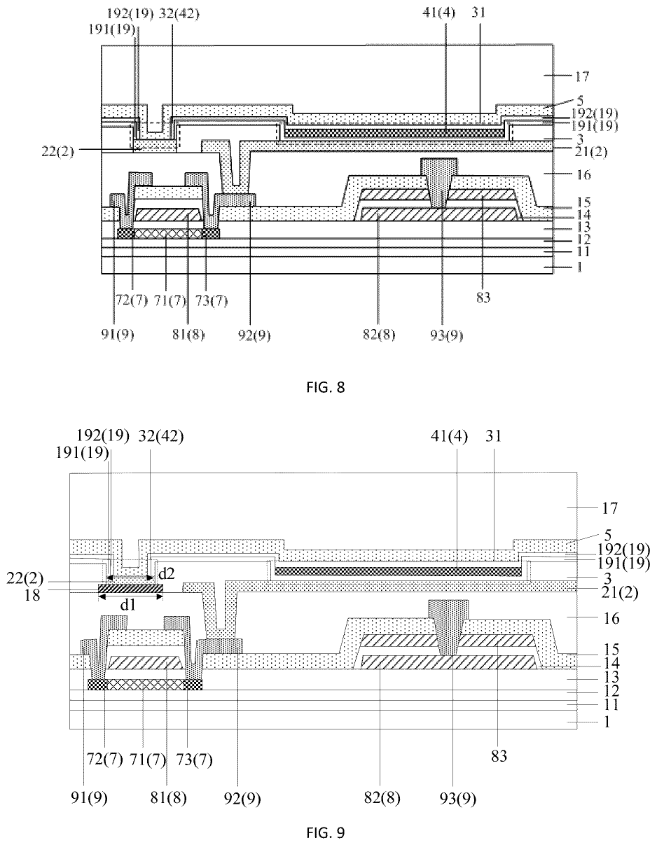

In some embodiments, as shown in FIG. 8 or FIG. 9, the display substrate further includes a packaging layer 17 at a side of the second electrode layer 5 facing away from the first electrode layer 2.

In some embodiments, as shown in FIG. 8 or FIG. 9, the packaging layer 17 may include a first inorganic packaging layer, an organic packaging layer, and a second inorganic packaging layer stacked in sequence.

Based on the same inventive conception, the embodiments of the disclosure further provide a display panel, and the display panel includes the display substrate provided in embodiments of the disclosure.

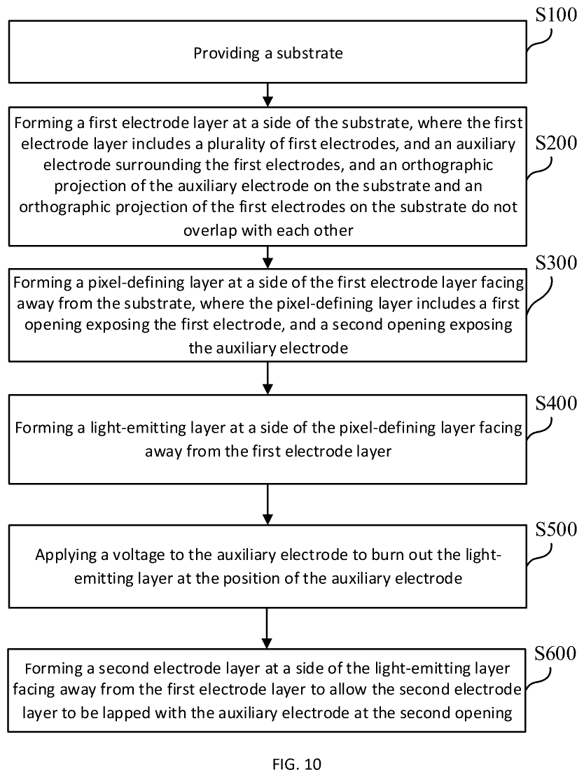

Based on the same inventive conception, the embodiments of the disclosure further provide a method for manufacturing the display substrate provided by the embodiments of the disclosure, as shown in FIG. 10, the manufacturing method includes following steps.
S100, providing the substrate.
S200, forming the first electrode layer at a side of the substrate, where the first electrode layer includes the plurality of first electrodes, and the auxiliary electrode surrounding the first electrodes, and the orthographic projection of the auxiliary electrode on the substrate and the orthographic projection of the first electrodes on the substrate do not overlap with each other. Specifically, in combination with FIGS. 1-9, processes such as sputtering, photo, exposure, and etching can be utilized to prepare the first electrode layer 2, and a ring-shaped metal surrounding the pixel region (i.e., the auxiliary electrode 22) can be simultaneously prepared; and pin pads (i.e., a first power pad 63, and a second power pad 64) required for applying voltage are prepared.
S300: forming the pixel-defining layer at a side of the first electrode layer facing away from the substrate, where the pixel-defining layer includes first openings exposing the first electrodes, and the second opening exposing the auxiliary electrode. Specifically, in connection with FIGS. 1-9, the pixel-defining layer 3 may be prepared using a process of coating, exposing, developing, etc., and openings at the positions corresponding a ring-shaped metal (i.e., the auxiliary electrode 22) and a power pad (i.e., the first power pad 63, and the second power pad 64) are added to this layer to expose the auxiliary electrode 22.
S400, forming the light-emitting layer at a side of the pixel-defining layer facing away from the first electrode layer.
S500, applying a voltage to the auxiliary electrode to burn out the light-emitting layer at the position of the auxiliary electrode.
S600, forming the second electrode layer at a side of the light-emitting layer facing away from the first electrode layer to allow the second electrode layer to lap with the auxiliary electrode at the second opening.

In the embodiments of the disclosure, the first electrode layer 2 includes a plurality of first electrodes 21, and an auxiliary electrode 22 located at the periphery of the first electrodes 21, and after preparing the light-emitting layer 4, the process of applying voltage to the auxiliary electrode 22 surrounding the first electrode 41 is added to cause the auxiliary electrode 22 surrounding the first electrode 41 to be heated up, which further causes the light-emitting layer 4 directly above the auxiliary electrode to be burned out, and then the second electrode layer 5 is formed. The conventional first electrode layer 2 is utilized as the auxiliary electrode, and the light-emitting layer 4 above the auxiliary electrode is removed by short-circuit heating to realize the lap connection between the auxiliary electrode with the second electrode layer 5, and to reduce the resistance of the second electrode layer 5.

Although the preferred embodiments of the disclosure have been described, those skilled in the art will be able to make additional changes and modifications to these embodiments once the basic inventive concepts are apparent. Therefore, it is intended that the appended claims be construed to include the preferred embodiments and all changes and modifications that fall within the scope of this disclosure.

Obviously, those skilled in the art can make various changes and modifications to the embodiments of the disclosure without departing from the spirit and scope of the embodiments of the disclosure. In this way, if these modifications and variations of the embodiments of the disclosure fall within the scope of the claims of the disclosure and equivalent technologies, the disclosure is also intended to include these modifications and variations.

1. A display substrate, comprising:
a substrate;
a first electrode layer at a side of the substrate, comprising a plurality of first electrodes, and an auxiliary electrode located at a periphery of the first electrodes; wherein an orthographic projection of the auxiliary electrode on the substrate and an orthographic projection of the first electrodes on the substrate do not overlap with each other;
a pixel-defining layer at a side of the first electrode layer facing away from the substrate, comprising a first opening exposing the first electrode, and a second opening exposing the auxiliary electrode;
a light-emitting layer at a side of the pixel-defining layer facing away from the first electrode layer, wherein the light-emitting layer comprises a light-emitting portion located in the first opening, and a hollow-out portion located in the second opening; and
a second electrode layer at a side of the light-emitting layer facing away from the pixel-defining layer, wherein the second electrode layer is lapped with the auxiliary electrode at the second opening.

2. The display substrate according to claim 1, wherein the auxiliary electrode is in a grid pattern having a plurality of third openings, and the plurality of first electrodes are located within the plurality of third openings.

3. The display substrate according to claim 2, wherein a gap is provided between the auxiliary electrode and the first electrode.

4. The display substrate according to claim 2, wherein a shape of the third opening is same as a shape of the first electrode located in the third opening.

5. The display substrate according to claim 2, wherein at least part of the third openings are of different sizes.

6. The display substrate according to claim 1, wherein
the first electrode layer further comprises a first connector located at an end of the auxiliary electrode, and a second connector located at the other end of the auxiliary electrode;
the first connector and the second connector is configured to apply a voltage to the auxiliary electrode to burn out the light-emitting layer at the second opening after forming the light-emitting layer, to form the hollow-out portion; and
an outer contour of the auxiliary electrode is a rectangle, and the first connector and the second connector are located at two ends of a diagonal of the rectangle, respectively.

7. The display substrate according to claim 6, wherein
the auxiliary electrode comprise a plurality of first sub-auxiliary electrodes extending in a first direction and arranged in a second direction, and a plurality of second sub-auxiliary electrodes connected with an adjacent first sub-auxiliary electrode; and
the first connector is connected with a first sub-auxiliary electrode located at an outer edge of the auxiliary electrode, and the second connector is connected with a first sub-auxiliary electrode at the other outer edge of the auxiliary electrode; and
part of the plurality of second sub-auxiliary electrodes are disconnected.

8. The display substrate according to claim 7, wherein
the plurality of first sub-auxiliary electrodes comprises first sub-electrode groups and second sub-electrode groups arranged alternately along the second direction; and the first sub-electrode group and the second sub-electrode group each comprises at least one of the plurality of first sub-auxiliary electrodes; and
the disconnected second sub-auxiliary electrode is located within the first sub-electrode group, and a same first sub-electrode group comprises at least one second sub-auxiliary electrode for connecting adjacent first sub-auxiliary electrodes.

9. The display substrate according to claim 8, wherein second sub-auxiliary electrodes for connecting adjacent first sub-auxiliary electrodes within two adjacent first sub-electrode groups are located at different ends of the display substrate in the first direction.

10. The display substrate according to claim 8, wherein second sub-electrode electrodes within the second sub-electrode group are all connected with the adjacent first sub-auxiliary electrodes.

11. The display substrate according to claim 8, wherein adjacent first sub-electrode group and second sub-electrode group share one first sub-auxiliary electrode.

12. The display substrate according to claim 1, wherein the display substrate further comprises a planarization layer between the substrate and the first electrode layer, and a heat insulating layer between the planarization layer and the first electrode layer and in contact with the auxiliary electrode;
wherein an orthographic projection of the heat insulating layer on the substrate covers the orthographic projection of the auxiliary electrode on the substrate, and the orthographic projection of the heat insulating layer on the substrate and the orthographic projection of the first electrodes on the substrate do not overlap with each other.

13. The display substrate according to claim 12, wherein the heat insulating layer has a grid pattern with a plurality of fourth openings in one-to-one correspondence with the third openings, and an orthographic projection of the third opening on the substrate covers an orthographic projection of the fourth opening on the substrate.

14. The display substrate according to claim 13, wherein a shape of the orthographic projection of the third opening on the substrate is same as a shape of the orthographic projection of the fourth opening on the substrate.

15. The display substrate according to claim 13, wherein a line width of the heat insulating layer is greater than a line width of the auxiliary electrode.

16. The display substrate according to claim 12, wherein a material of the heat insulating layer comprises: silicon dioxide or silicon nitride.

17. (canceled)

18. (canceled)

19. (canceled)

20. (canceled)

21. The display substrate according to claim 1, wherein the display substrate further comprises a light-emitting functional portion at an inner wall of the second opening.

22. The display substrate according to claim 21, wherein
the light-emitting functional portion comprises: a first sub light-emitting functional portion, and a second sub light-emitting functional portion located at a side of the first sub light-emitting functional portion away from the inner wall of the second opening;
the first sub light-emitting functional portion comprises: a hole transport layer and/or an electron blocking layer; and
the second sub-luminescent functional portion comprises: an electron transport layer and/or a hole blocking layer.

23. A display apparatus, comprising the display substrate according to claim 1.

24. A method for manufacturing the display substrate according to claim 1, comprising:
providing the substrate;
forming the first electrode layer at a side of the substrate,
forming the pixel-defining layer at a side of the first electrode layer facing away from the substrate
forming the light-emitting layer at a side of the pixel-defining layer facing away from the first electrode layer;
applying a voltage to the auxiliary electrode to burn out the light-emitting layer at a position of the auxiliary electrode; and
forming the second electrode layer at a side of the light-emitting layer facing away from the first electrode layer to allow the second electrode layer to be lapped with the auxiliary electrode at the second opening.
